(19) United States
(12) Patent Application Publication
(10) Pub. No.: US 2021/0210538 A1
(43) Pub. Date: Jul. 8, 2021

(54) CHIP PACKAGE AND METHOD FOR FORMING THE SAME

(71) Applicant: XINTEC INC., Taoyuan City (TW)

(72) Inventors: Jiun-Yen LAI, Taipei City (TW); Wei-Luen SUEN, New Taipei City (TW); Hsing-Lung SHEN, Hsinchu City (TW); Yu-Ting HUANG, Taoyuan City (TW)

(21) Appl. No.: 17/133,636

(22) Filed: Dec. 24, 2020

Related U.S. Application Data
(60) Provisional application No. 62/956,549, filed on Jan. 2, 2020.

(51) Int. Cl. H01L 27/146

(52) U.S. Cl. CPC H01L 27/14632; H01L 27/14687; H01L 27/14636; H01L 27/14618

(57) ABSTRACT

A chip package is provided. The chip package includes a first substrate and a second substrate disposed over the first substrate. The first substrate and the second substrate have a lower surface and an upper surface, and the second substrate includes a first recess region surrounding the second substrate. The first recess region has a tapered sidewall and a bottom surface that is between the lower and upper surfaces of the second substrate. The chip package also includes at least one conductive pad disposed on the upper surface of the second substrate and a redistribution layer (RDL) correspondingly disposed on the conductive pad. The RDL is extended from the conductive pad onto the bottom surface of the first recess region along the tapered sidewall of the first recess region. A method of forming a chip package is also provided.

### CROSS REFERENCE TO RELATED APPLICATIONS

This application claims the benefit of U.S. Provisional Application No. 62/956,549, filed Jan. 2, 2020, the entirety of which is incorporated by reference herein.

### BACKGROUND OF THE INVENTION

### Field of the Invention

The present invention relates to chip package technology, and in particular to a chip package and a method for forming the same.

### Description of the Related Art

As demand increases for electronic and optoelectronic products such as mobile phones, optical chip packages using transparent or opaque substrates (e.g., silicon, glass, quartz or the like) must be developed rapidly, as product trends require miniaturization of the chip package. The chip package process is becoming an important process in the fabrication of electronic and optoelectronic products, due to performance demands, and for operational stability.

The chip package includes substrates (e.g., glass substrates or silicon substrates) that are bonded to each other. When the chip package is applied to an optical device, the housing where the optical components (e.g., lens) and circuits are placed is attached to the pads on the chip package via conductive glue (e.g., silver paste), so that the housing and the chip package are electrically connected to each other to form a chip package assembly. However, in the manufacture of the above-mentioned chip package assembly, the conductive glue may easily squeeze onto the surface of the chip package corresponding to the active area during the attaching of the chip package and the housing. Therefore, the optical path of the chip package is contaminated and thus the yield of the chip package assembly is reduced. This makes it more difficult to manufacture the chip package.

Accordingly, there is a need for a novel chip package and methods for forming the same capable of eliminating or mitigating the aforementioned problems.

### BRIEF SUMMARY OF THE INVENTION

An embodiment of the invention provides a chip package which includes a first substrate having a lower surface and an upper surface. A second substrate is disposed on the first substrate, having a lower surface and an upper surface, and having a first recess region. The first recess region surrounds the second substrate and has a tapered sidewall and a bottom surface that is between the lower and upper surfaces of the second substrate. At least one conductive pad is disposed on the upper surface of the second substrate. A redistribution liner is correspondingly disposed on the conductive pad and extends from the conductive pad and along the tapered sidewall of the first recess region to the bottom surface of the first recess region.

An embodiment of the invention provides a method for forming a chip package that includes providing a first substrate and a second substrate. Each of the first substrate and the second has a lower surface and an upper surface, and has at least one chip region and a scribe line region surrounding the chip region. At least one conductive pad is formed on the upper surface of the second substrate and in the chip region thereof. The upper surface of the first substrate is bonded with the lower surface of the second substrate. A first opening is formed in the scribe line region of the second substrate to surround the chip region of the second substrate. The first opening has a tapered sidewall and a bottom surface that is between the lower and upper surfaces of the second substrate. A redistribution layer is correspondingly formed onto the conductive pad and extends from the tapered sidewall of the first opening to the bottom surface of the first opening. The second substrate and the first substrate below the first opening are diced.

### BRIEF DESCRIPTION OF THE DRAWINGS

The present invention can be more fully understood by reading the subsequent detailed description and examples with references made to the accompanying drawings, wherein:

FIG. 1 is a cross-sectional view of an exemplary embodiment of a chip package in accordance with some embodiments of the invention.

FIGS. 2A to 2G are cross-sectional views of an exemplary embodiment of a method for forming a chip package in accordance with some embodiments of the invention.

FIG. 3 is a cross-sectional view of an exemplary embodiment of a chip package in accordance with some embodiments of the invention.

FIG. 4 is a cross-sectional view of an exemplary embodiment of a chip package in accordance with some embodiments of the invention.

FIG. 5 is a cross-sectional view of an exemplary embodiment of a chip package in accordance with some embodiments of the invention.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Furthermore, when a first material layer is referred to as being on or overlying a second material layer, the first material layer may be in direct contact with the second material layer, or separated from the second material layer by one or more material layers.

The optical chip package of the embodiments of the invention may be implemented to package active or passive devices or electronic components of integrated circuits, such as digital or analog circuits. For example, the optical chip package is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to fabricate such an optical chip package.

The above-mentioned wafer-level package process mainly means that after the packaging step is accomplished during the wafer stage, the wafer with chips is cut to obtain individual packages. In addition, the above-mentioned wafer-level package process may also be adapted to form an optical chip package having multi-layer integrated circuit devices by a stack of wafers having integrated circuits.

The following embodiments may discuss specific examples. However, those skilled in the art will recognize that various applications can be used in some other embodiments when they read the present disclosure. It should be noted that the embodiments discussed herein may not describe each of elements that may exist in the structure. For example, the element may be omitted in the accompanying figures when various aspects of the embodiments can be sufficiently expressed through the discussion of the element. Moreover, the embodiments discussed herein may not describe each of manufacturing steps, and the method of forming the chip package may be discussed using a specific manufacturing step order. However, in some other embodiments, the chip package can be fabricated by any reasonable manufacturing step order.

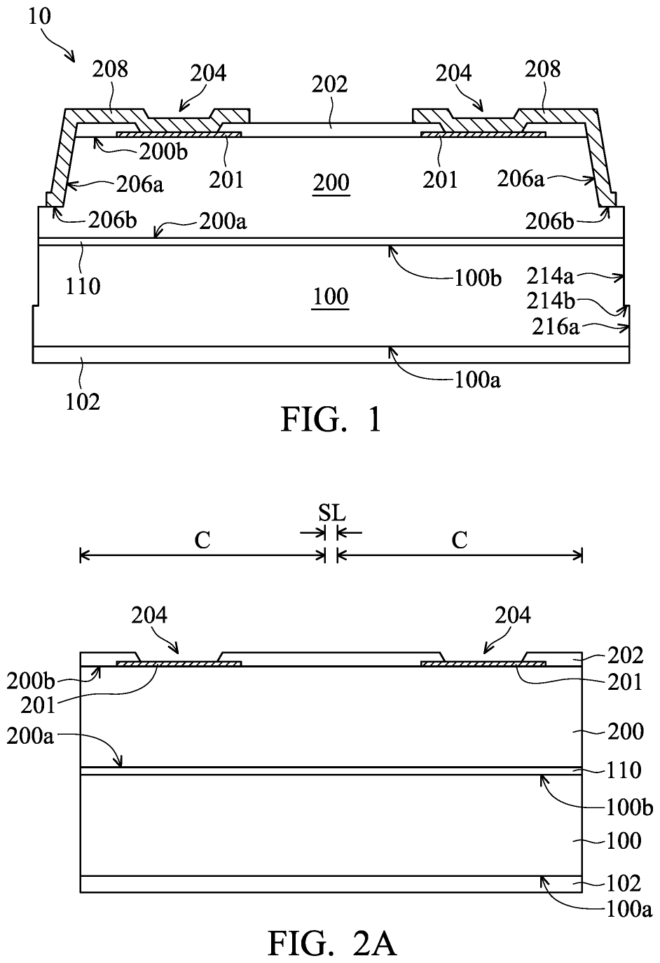

Refer to FIG. 1, which illustrates a cross-sectional view of an exemplary embodiment of a chip package 10 in accordance with some embodiments of the invention. In some embodiments, the chip package 10 includes a first substrate 100. In some embodiments, the first substrate 100 is made of silicon, glass, quartz, or a molding compound material. The first substrate 100 has a lower surface 100a and an upper surface 100b opposite the lower surface 100a.

In some embodiments, the chip package 10 further includes a first insulating layer 102 disposed on the lower surface 100a of the first substrate 100. In some embodiments, the first insulating layer 102 includes an interlayer dielectric (ILD) layer, an inter-metal dielectric (IMD) layer, a passivation layer or a combination thereof. The first insulating layer 102 may include an inorganic material, such as silicon oxide, silicon nitride, silicon oxynitride, metal oxide, or a combination thereof, or another suitable insulating material.

In some embodiments, one or more conductive pads (not shown) and interconnects (not shown) electrically connected to the conductive pads are formed in the first insulating layer 102. To simplify the diagram, only a flat layer is depicted. In some other embodiments, there are not conductive pads and interconnects formed in the first insulating layer 102. In some embodiments, the first insulating layer 102 and the first substrate 100 form a first chip.

In some other embodiments, the first substrate 100 is made of a transparent material and the chip package 10 further includes an optical material layer (not shown) disposed on the upper surface 100b of the first substrate 100. The surface of the optical material layer opposite to the upper surface 100b of the first substrate 100 includes an optical pattern to change the optical path of the incident light passing through the optical material layer. In some embodiments, the optical material layer, the first insulating layer 102, and the first substrate 100 form a first chip.

In some embodiments, the chip package 10 further includes a second substrate 200. In some embodiments, the second substrate 200 is made of silicon, glass, quartz, or a molding compound material. The second substrate 200 has a lower surface 200a and an upper surface 200b opposite the lower surface 200a. Moreover, the second substrate 200 is disposed over the first substrate 100, so that the upper surface 200b of the second substrate 200 is opposite to the lower surface 100a of the first substrate 100. In addition, the second substrate 200 may include an active area (not shown) therein. The active area may include an optical device (not shown) therein. For example, the active area may include an image sensing device or another suitable optical device therein.

In some embodiments, the second substrate 200 has a first recess region downwardly extending into the second substrate 200 from the upper surface 200b thereof, and surrounding the second substrate 200. That is, the first recess region surrounds the active area of the second substrate 200 along the edges of the second substrate 200. In some embodiments, the first recess region has a tapered sidewall 206a and a bottom surface 206b that is between the lower and upper surfaces 200a and 200b of the second substrate 200.

In some embodiments, the chip package 10 further includes one or more conductive pads 201 disposed on the upper surface 200b of the second substrate 200 and outside of the active area of the second substrate 200, so as to be electrically connected to an external circuit (not shown). In some embodiments, the conductive pads 201 are formed of a single conductive layer (e.g., a metal layer) or multiple conductive layers. To simplify the diagram, only few conductive pads 201 including a single conductive layer are depicted herein as an example.

In some embodiments, the chip package 10 further includes a second insulating layer 202 disposed on the upper surface 200b of the second substrate 200 and covering a portion of each conductive pad 201. For example, the second insulating layer 202 includes openings 204 exposing the corresponding conductive pads 201. In some embodiments, the second insulating layer 202 includes an interlayer dielectric (ILD) layer, an inter-metal dielectric (IMD) layer, a passivation layer or a combination thereof. In some embodiments, the second insulating layer 202 includes an inorganic material, such as silicon oxide, silicon nitride, silicon oxynitride, metal oxide, or a combination thereof, or another suitable insulating material. Moreover, one or more conductive pads (not shown) and interconnects (not shown) electrically connected to the conductive pads are formed in the second insulating layer 202. In some embodiments, the conductive pads 201, the second insulating layer 202, and the second substrate 200 form a second chip.

In some other embodiments, the second substrate 200 is made of a transparent material and an optical material layer (not shown) disposed on the lower surface 200a of the second substrate 200. The surface of the optical material layer opposite to the lower surface 200a of the second substrate 200 includes an optical pattern to change the optical path of the incident light passing through the optical material layer. In some embodiments, the optical material layer, the conductive pads 201, the second insulating layer 202, and the second substrate 200 form a second chip.

In some embodiments, the chip package 10 further includes a bonding material layer 110 disposed between the first substrate 100 and the second substrate 200, so as to attach the upper substrate 100b of the first substrate 100 with the lower surface 200a of the second substrate 200. In some embodiments, the bonding material layer 110 covers the upper substrate 100b of the first substrate 100 and the lower surface 200a of the second substrate 200, so that there is no cavity between the first substrate 100 and the second substrate 200. In some embodiments, the bonding material layer does not substantially absorb moisture and is non-adhesive. In those cases, the first chip, the second chip, and the bonding material layer 110 are bonded using additional adhesion glues.

In some other embodiments, the bonding material layer 110 may itself be adhesive. In those cases, the first chip can attach to the second chip by the bonding material layer 110. As a result, the bonding material layer 110 may contact none of the adhesion glue, thereby assuring that the bonding material layer 110 will not move due to the disposition of the adhesion glue.

In some embodiments, the bonding material layer 110 is made of a transparent insulating material that includes an epoxy resin, an inorganic material (such as silicon oxide, silicon nitride, silicon oxynitride, metal oxide, or a combination thereof), an organic polymer material (such as polyimide, butylcyclobutene (BCB), parylene, polynaphthalenes, fluorocarbons or acrylates), a photoresist material, or another suitable insulating layer.

In some embodiments, the chip package 10 further includes one or more redistribution layers 208 that are correspondingly disposed on the conductive pads 201 through the openings 204 of the second insulating layer 202. Moreover, the redistribution layer 208 outside of the opening 204 extends onto the bottom surface 206b of the first recess region from the conductive pad 201 and along the tapered sidewall 206a of the first recess region. As a result, the second insulating layer 202 is formed between the second substrate 200 and the redistribution layers 208, and the redistribution layer 208 in the opening 204 of the second insulating layer 202 is electrically connected to the conductive pad 201. In some embodiments, the redistribution layers 208 are made of metal. In some embodiments, the second substrate 200 is made of silicon, and an insulating liner (not shown) is formed between the redistribution layers 208 and the second substrate 200, so that the redistribution layers 208 are electrically isolated from the second substrate 200.

In some embodiments, the chip package 10 further includes a second recess region that downwardly extends into the first substrate 100 from the bottom surface 206b of the first recess region, and surrounds the second substrate 200 and the first substrate 100. That is, the second recess region surrounds the active area (not shown) of the second substrate 200 and the active area (not shown) of the first substrate 100 along the edges of the second and first substrates 200 and 100. In some embodiments, the second recess region has a sidewall 214a and a bottom surface 214b that is between the lower and upper surfaces 100a and 100b of the first substrate 100.

Moreover, the first substrate 100 has a sidewall 216a that downwardly extends to the lower surface 100a of the first substrate 100 from the bottom surface 214b of the second recess region. In some embodiments, the sidewall 214a and the sidewall 216a are vertical sidewalls. In some embodiments, the tapered sidewall 206a, the sidewall 214a, and the sidewall 216a are not aligned to each other, so that the first substrate 100 and the second substrate 200 have a stepped sidewall (which includes the tapered sidewall 206a, the sidewall 214a, and the sidewall 216a) formed of the first recess region and the second recess region.

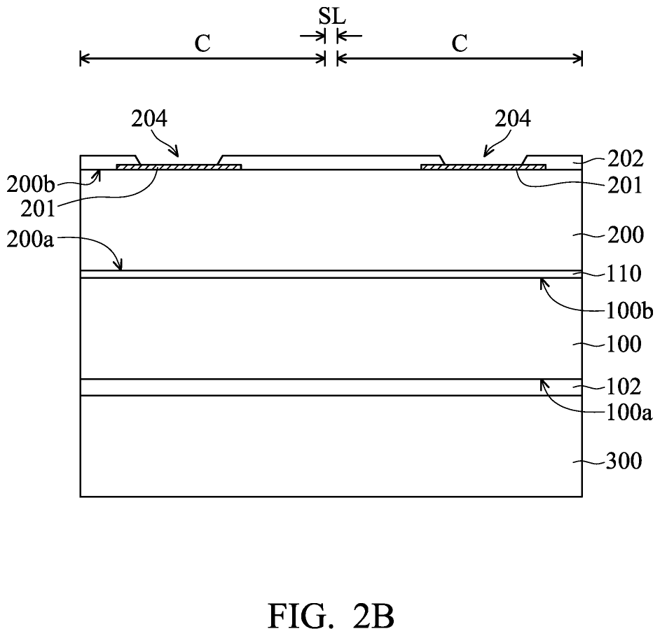

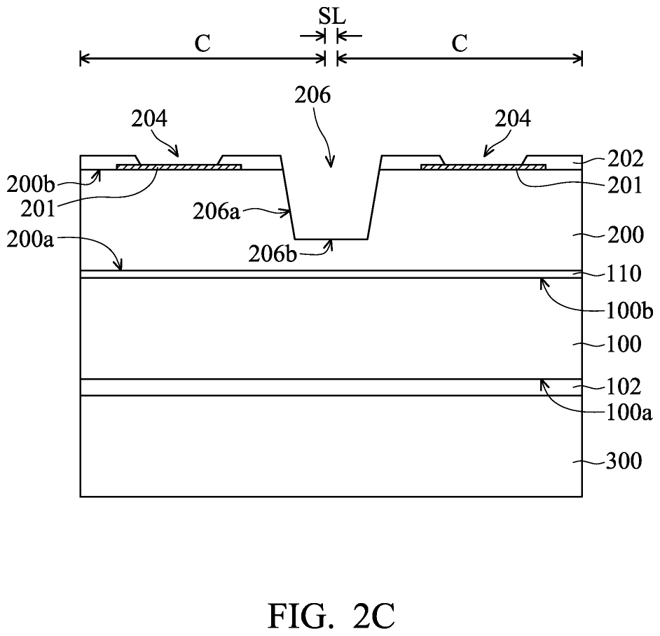

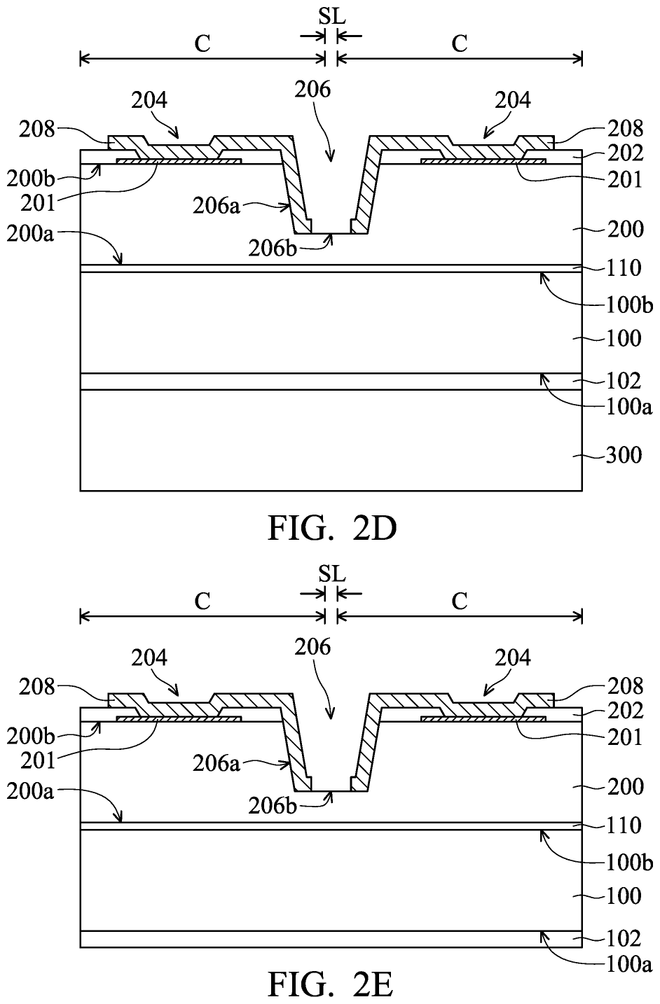

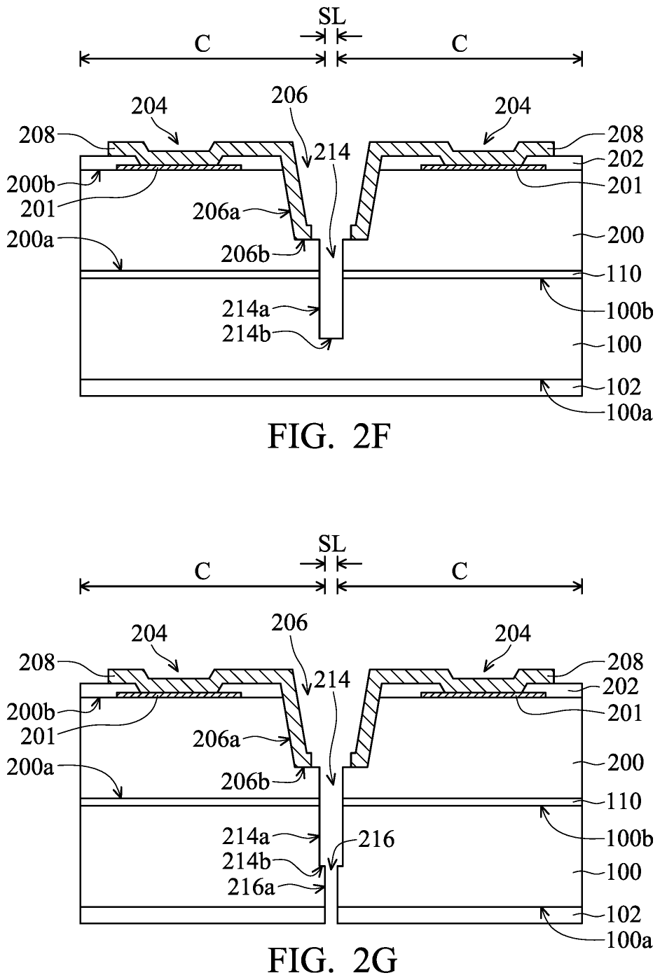

FIGS. 2A to 2G are cross-sectional views of an exemplary embodiment of a method for forming a chip package 10 in accordance with some embodiments of the invention. Elements in FIGS. 2A to 2H that are the same as those in FIG. 1 are labeled with the same reference numbers as in FIG. 1 and are not described again for brevity. Refer to FIG. 2A, a first substrate 100 and a second substrate 200 are provided. The first substrate 100 has a lower surface 100a and an upper surface 100b opposite thereto, and may include chip regions and a scribe line region that surrounds these chip regions and separates the adjacent chip regions from each other. Moreover, each chip region includes an active area (not shown). Similarly, the second substrate 200 has a lower surface 200a and an upper surface 200b opposite thereto, and may include chip regions and a scribe line region that surrounds these chip regions and separates the adjacent chip regions from each other. To simplify the diagram, only portions of two adjacent chip regions C, and a scribe line region SL separating these chip regions C are depicted herein.

In some embodiments, the first substrate 100 and the second substrate 110 are wafers so as to facilitate the wafer-level packaging process. In some embodiments, the wafers are made of silicon, glass, quartz, or a molding compound material. Afterwards, a first insulating layer 102 is formed on the lower surface 100b of the first substrate 100. Moreover, one or more conductive pads 201 and a second insulating layer 202 are successively formed on the upper surface 200b of the second substrate 200. The second insulating layer 202 covers a portion of each conductive pad 201. For example, the second insulating layer 202 has openings 204 exposing the corresponding conductive pads 201.

In some other embodiments, an optical material layer (not shown) that has an optical pattern is formed on the upper surface 100b of the first substrate 100 before or after the first insulating layer 102 is formed. Similarly, another optical material layer (not shown) that has an optical pattern is formed on the lower surface 200a of the second substrate 200 before or after the conductive pads 201 and the second insulating layer 202.

In some embodiments, after the first insulating layer 102 and the second insulating layer 202 are formed, the upper surface 100b of the first substrate 100 is bonded to the lower surface 200a of the second substrate 200. In some embodiments, the first substrate 100 is bonded to the second substrate 200 through a bonding material layer 110, so that the bonding material layer 110 is formed between the upper surface 100b of the first substrate 100 and the lower surface 200a of the second substrate 200.

In some embodiments, the bonding material layer 110 is made of a transparent material and is adhesive or non-adhesive. For example, in the case of the non-adhesive bonding material layer 110 can use additional adhesion glues to bond the first substrate 100 to the second substrate 200 via the bonding material layer 110. In some embodiments, the bonding material layer 110 is formed by a deposition process (e.g., a coating process, a physical vapor deposition process, a chemical vapor deposition process, or another suitable process). In some embodiments, the bonding material layer 110 covers the upper surface 100b of the first substrate 100 and the lower surface 200a of the second substrate 200, so that there is no cavity between the first substrate 100 and the second substrate 200.

In some other embodiments, the first substrate 100 and the second substrate 200 are made of a transparent material (e.g., glass or quartz). Moreover, the first substrate 100 has an optical material layer (not shown) formed on the upper surface 100b thereof, and the second substrate 200 has another optical material layer (not shown) formed on the lower surface 200a thereof. The bonding material layer 110 is bonded to the first substrate 100 and the second substrate 300, so that the bonding material layer 110 is formed between those optical material layers.

Refer to FIG. 2B, in some embodiments, after the first substrate 100 is bonded to the second substrate 200, the first insulating layer 102 on the first substrate 100 is attached onto a carrier substrate 300 (e.g., a tape layer).

Refer to FIG. 2C, in some embodiments, a first opening 206 is formed to correspond to the scribe line region SL of the second substrate 200 and surround the chip regions C of the second substrate 200. For example, a dicing process is performed on the second insulating layer 202 on the upper surface 200b of the second substrate 200 by a dicing saw (not shown), to form the first opening 206 in the scribe line region SL of the second substrate 200. In some embodiments, the first opening 206 has a tapered sidewall 206a and a bottom surface 206b that is between the lower and upper surfaces 200a and 200b of the second substrate 200.

Refer to FIG. 2D, one or more redistribution layers 208 are formed on the upper surface 200b of the second substrate 200 and the inner surface (e.g., the tapered sidewall 206a and the bottom surface 206b) of the first opening 206, so as to be electrically connected to the corresponding conductive pad 201.

For example, a conductive layer (not shown) is formed on the upper surface of the second insulating layer 202 on the second substrate 200 and conformally on the inner surface of the first opening 206 by a deposition process (e.g., a coating process, a physical vapor deposition process, a chemical vapor deposition process, or another suitable process), so as to extend into the second substrate 200. In some embodiments, the conductive layer is made of opaque conductive material, such as metal. Afterwards, a patterning process (e.g., lithography and etching processes) is performed on the conductive layer to form the redistribution layers 208, so that the second insulating layer 202 is formed between the second substrate 200 and the redistribution layers 208. The formed redistribution layers 208 extend from the corresponding conductive pad 201 and along the tapered sidewall 206a of the first opening 206 to the bottom surface 206b of the first opening 206.

In some embodiments, the second substrate 200 is made of silicon. In those cases, an insulating liner (not shown) is formed on the inner surface of the first opening 206 prior to the formation of the conductive layer that is used for forming the redistribution layers 208, so that the subsequently formed redistribution layers 208 are electrically isolated from the second substrate 200.

After the formation of the redistribution layers 208, the carrier substrate 300 is removed, as shown in FIG. 2E. Refer to FIGS. 2F and 2G, the second substrate 200 and the first substrate 100 below the first opening 206 are diced to pass through the scribe line region SL corresponding to the first substrate 100 and the second substrate 200, and thus individual chip packages 10 (as shown in FIG. 1) are formed.

As shown in FIG. 2F, in some embodiments, a second opening 214 is formed below the first opening 206. More specifically, the second opening 214 downwardly extends from the bottom surface 206b of the first opening 206 into the first substrate 100 and surrounds the second substrate 200 and the first substrate 100. For example, a dicing process is performed by a dicing saw (not shown), to form the second opening 214 below the bottom of the first opening 206. In some embodiments, the second opening 214 has a sidewall 214a and a bottom surface 214b that is between the lower and upper surfaces 100a and 100b of the first substrate 100. Unlike the tapered sidewall 206a of the first opening 206, the sidewall 214b is a vertical sidewall. Moreover, the bottom width of the first opening 206 is greater than the top width of the second opening 214, so that the top end of the sidewall 214a of the second opening 214 does not overlap the bottom end of the tapered sidewall 206a of the first opening 206. As a result, the first substrate 100 and the second substrate 200 have a first recess region formed of the first opening 206 and a second recess region formed of the second opening 214.

Refer to FIG. 2G, in some embodiments, a third opening 216 is formed below the second opening 214. More specifically, the third opening 216 downwardly extends from the bottom surface 214b of the second opening 214 to the lower surface 100a of the first substrate 100 and passes through the first insulating layer 102. Similar to the second opening 214, the third opening 216 surrounds the first substrate 100. For example, a dicing process is performed by a dicing saw (not shown), to form the third opening 216 below the bottom of the second opening 214. In some embodiments, the third opening 216 has a sidewall 216a. Similar to the sidewall 214a of the second opening 214, the sidewall 216a is a vertical sidewall. Moreover, the bottom width of the second opening 214 is greater than the top width of the third opening 216, so that the bottom end of the sidewall 214a of the second opening 214 does not overlap the top end of the sidewall 216a of the third opening 216. As a result, the first substrate 100 and the second substrate 200 have a stepped sidewall formed of the first opening 206, the second opening 216 and the third opening 218.

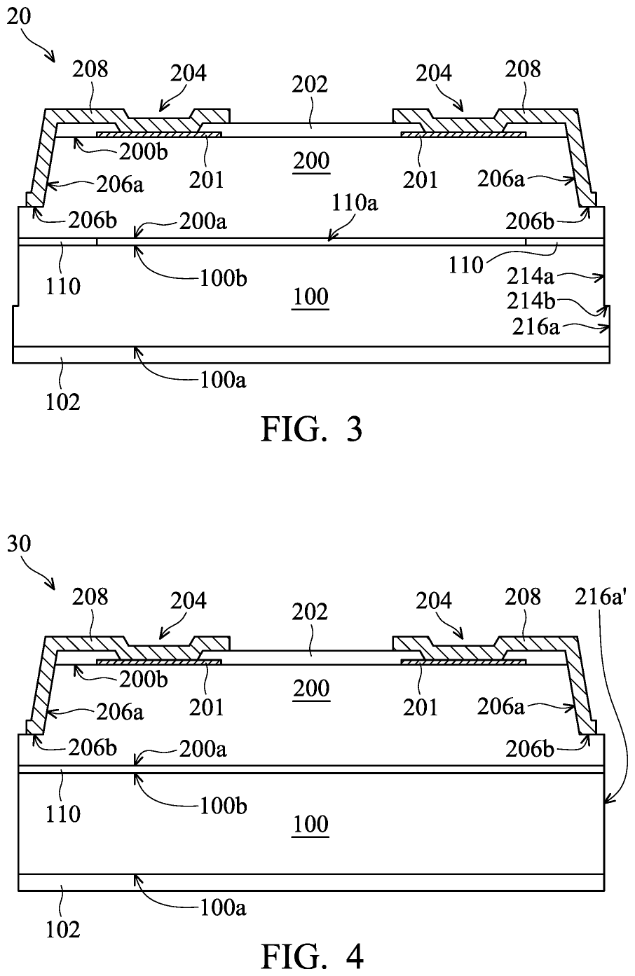

Refer to FIG. 3, which is a cross-sectional view of an exemplary embodiment of a chip package 20 in accordance with some embodiments of the invention. Elements in FIG. 3 that are the same as those in FIG. 1 are labeled with the same reference numbers as in FIG. 1 and are not described again for brevity. In some embodiments, the structure of the chip package 20 is similar to that of the chip package 10 shown in FIG. 1. Therefore, the chip package 20 can be formed by using a method that is the same as or similar to the method shown in FIGS. 2A to 2G. However, the difference between the chip package 20 and the chip package 10 is that the bonding material layer 110 in the package chip 20 has an opening, so as to form a cavity 110a between the upper surface 100b of the first substrate 100 and the lower surface 200a of the second substrate 200. The cavity 110a corresponds to the chip region C of the first substrate 100 and the chip region C of the second substrate 200. The bonding material layer 110 having the opening may be made of an opaque insulating material.

Refer to FIG. 4, which is a cross-sectional view of an exemplary embodiment of a chip package 30 in accordance with some embodiments of the invention. Elements in FIG. 4 that are the same as those in FIG. 1 are labeled with the same reference numbers as in FIG. 1 and are not described again for brevity. In some embodiments, the structure of the chip package 30 is similar to that of the chip package 10 shown in FIG. 1. Therefore, the chip package 30 can be formed by using a method that is the same as or similar to the method shown in FIGS. 2A to 2G. However, the difference between the chip package 30 and the chip package 10 is that the second substrate 200 and the first substrate in the chip package 30 have a sidewall 216a′ downwardly extending to the lower surface 100a of the first substrate 100. In some embodiments, the tapered sidewall 206a and the sidewall 216a′ are not aligned to each other, so that the first substrate 100 and the second substrate 200 have a stepped sidewall (which includes the tapered sidewall 206a and the sidewall 216a′) formed of the first recess region. In some embodiments, the chip package 30 is formed by using a similar method to the method shown in FIGS. 2A to 2G. After the first opening 206 and the redistribution layers 208 are formed by using, for example, the method shown in FIGS. 2A to 2E, a dicing process is performed by a dicing saw (not shown). As a result, an opening downwardly extending to the lower surface 100a of the first substrate 100 from the bottom surface 206b of the first opening 206, and passing through the first insulating layer 102 (as shown in FIG. 2G) is formed. This opening has a vertical sidewall.

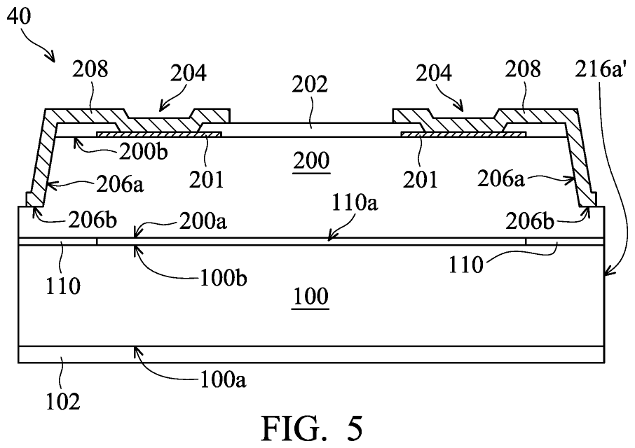

Refer to FIG. 5, which is a cross-sectional view of an exemplary embodiment of a chip package 40 in accordance with some embodiments of the invention. Elements in FIG. 5 that are the same as those in FIG. 4 are labeled with the same reference numbers as in FIG. 4 and are not described again for brevity. In some embodiments, the structure of the chip package 40 is similar to that of the chip package 30 shown in FIG. 4. Therefore, the chip package 40 can be formed by using a method that is the same as or similar to the method shown in FIGS. 2A to 2G. However, the difference between the chip package 40 and the chip package 30 is that the bonding material layer 110 in the package chip 40 has an opening, so as to form a cavity 110a between the upper surface 100b of the first substrate 100 and the lower surface 200a of the second substrate 200. The cavity 110a corresponds to the chip region C of the first substrate 100 and the chip region C of the second substrate 200. The bonding material layer 110 having the opening may be made of an opaque insulating material.

According to the aforementioned embodiments, in the manufacture of chip package assembly, during the attaching of the chip package with the housing, the first recess region of the chip package can be used to accommodate excess conductive glue, thereby preventing the conductive glue from squeezing onto the surface of the chip package corresponding to the active area. As a result, contamination of the optical path of the chip package can be avoided or mitigated, thereby improving the yield of the chip package assembly and reducing the manufacturing difficulty of the chip package assembly. Moreover, the first recess region in the chip package can also accommodate a portion of the housing, so that the overall height of the chip package assembly is reduced. Therefore, the size of the chip package assembly is reduced. In addition, since the redistribution layer in the chip package extends on the tapered sidewall of the first recess region, the electrical contact area between the housing and the chip package can be increased during the manufacture of the chip package assembly, thereby increasing reliability of chip package assembly.

According to the aforementioned embodiments, in the manufacture of chip package, the stepped sidewall can be accomplished by performing a multi-step dicing process using dicing saws with different sizes. Compared with the use of a single dicing saw to perform the single dicing process, the loading of the dicing saw can be reduced, thereby increasing the stability of the dicing process and preventing or mitigating chipping of the chip package.

While the invention has been disclosed in terms of the preferred embodiments, it is not limited. The various embodiments may be modified and combined by those skilled in the art without departing from the concept and scope of the invention.

What is claimed is:

1. A chip package, comprising:
a first substrate having a lower surface and an upper surface;
a second substrate disposed on the first substrate, having a lower surface and an upper surface, and having a first recess region, wherein the first recess region surrounds the second substrate and has a tapered sidewall and a bottom surface that is between the lower and upper surfaces of the second substrate;
at least one conductive pad disposed on the upper surface of the second substrate; and
a redistribution liner disposed on the conductive pad, wherein the redistribution liner extends out from the conductive pad, along the tapered sidewall of the first recess region, and to the bottom surface of the first recess region.

2. The chip package as claimed in claim 1, further comprising:
a bonding material layer bonding the upper surface of the first substrate to the lower surface of the second substrate.

3. The chip package as claimed in claim 2, wherein the bonding material layer has an opening that forms a cavity between the upper surface of the first substrate and the lower surface of the second substrate.

4. The chip package as claimed in claim 3, wherein the bonding material layer is made of an opaque insulating material.

5. The chip package as claimed in claim 1, wherein the bonding material layer is made of a transparent insulating material.

6. The chip package as claimed in claim 1, further comprising:
a second recess region downwardly extending from the bottom surface of the first recess region to a level between the upper and lower surfaces of the first substrate, wherein the second recess region surrounds the second substrate and the first substrate.

7. The chip package as claimed in claim 6, wherein the second recess region has a vertical sidewall.

8. The chip package as claimed in claim 6, wherein the first substrate and the second substrate have a stepped sidewall formed of the first recess region and the second recess region.

9. The chip package as claimed in claim 1, further comprising:
a first passivation layer disposed on the lower surface of the first substrate; and
a second passivation layer disposed between the second substrate and the redistribution layer and covering a portion of the conductive pad.

10. The chip package as claimed in claim 1, wherein the first substrate or the second substrate is made of silicon, glass, quartz, or a molding compound material.

11. The chip package as claimed in claim 1, wherein the first substrate and the second substrate has a vertical sidewall downwardly extending to the lower surface of the first substrate from the bottom surface of the first recess region.

12. A method for forming a chip package, comprising:
providing a first substrate and a second substrate, wherein each of the first substrate and the second substrate has a lower surface and an upper surface, and has at least one chip region and a scribe line region surrounding the chip region;
forming at least one conductive pad on the upper surface of the second substrate and in the chip region thereof;
bonding the upper surface of the first substrate to the lower surface of the second substrate;
forming a first opening in the scribe line region of the second substrate to surround the chip region of the second substrate, wherein the first opening has a tapered sidewall and a bottom surface that is between the lower and upper surfaces of the second substrate;
forming a redistribution layer on the conductive pad, wherein the redistribution layer extends from the tapered sidewall of the first opening to the bottom surface of the first opening; and
dicing the second substrate and the first substrate below the first opening.

13. The method for forming a chip package as claimed in claim 12, wherein the upper surface of the first substrate is bonded to the lower surface of the second substrate via a bonding material layer.

14. The method for forming a chip package as claimed in claim 13, wherein the bonding material layer has an opening that forms a cavity between the upper surface of the first substrate and the lower surface of the second substrate, and wherein the cavity corresponds to the chip region of the first substrate and the chip region of the second substrate.

15. The method for forming a chip package as claimed in claim 14, wherein the bonding material layer is made of an opaque insulating material.

16. The method for forming a chip package as claimed in claim 12, wherein dicing the second substrate and the first substrate further comprises:
forming a second opening below the first opening, wherein the second opening downwardly extends from the bottom surface of the first opening to a level between the upper and lower surfaces of the first substrate, and surrounds the second substrate and the first substrate; and
forming a third opening below the second opening, wherein the third opening downwardly extends from a bottom surface of the second opening to the lower surface of the first substrate, and surrounds the first substrate.

17. The method for forming a chip package as claimed in claim 16, wherein each of the second opening and the third opening has a vertical sidewall.

18. The method for forming a chip package as claimed in claim 15, wherein the first and second substrates have a stepped sidewall formed of the first opening, the second opening, and the third opening.

19. The method for forming a chip package as claimed in claim 12, wherein dicing the second substrate and the first substrate further comprises:
forming a first passivation layer on the lower surface of the first substrate; and
forming a second passivation layer on the upper surface of the second substrate and covering a portion of the conductive pad.

20. The method for forming a chip package as claimed in claim 12, wherein the first substrate or the second substrate is made of silicon, glass, quartz, or a molding compound material.

21. The method for forming a chip package as claimed in claim 11, wherein the bonding material layer is made of a transparent insulating material.

22. The method for forming a chip package as claimed in claim 12, further comprising:
forming a second opening below the first opening, wherein the second opening downwardly extends from the bottom surface of the first opening to the lower surface of the first substrate, and surrounds the first substrate.

23. The method for forming a chip package as claimed in claim 22, wherein the second opening has a vertical sidewall.
